(19) United States
(12) Patent Application Publication
(10) Pub. No.: US 2026/0271197 A1
(43) Pub. Date: Sep. 10, 2026

(54) ELECTRONIC CONTROL DEVICE AND METHOD OF MANUFACTURING THE SAME

(71) Applicant: Astemo, Ltd., Chiyoda-ku, Tokyo (JP)

(72) Inventor: Junichi SHIMANE, Hitachinaka-shi, Ibaraki (JP)

(73) Assignee: Astemo, Ltd., Chiyoda-ku, Tokyo (JP)

(21) Appl. No.: 19/160,896

(22) PCT Filed: Jun. 29, 2023
(86) PCT No.: PCT/JP2023/024243

§ 371 Date: Aug. 29, 2025

(51) Int. Cl. H05K 5/00; H05K 5/04

(52) U.S. Cl. CPC H05K 5/0069; H05K 5/04

(57) ABSTRACT

In order to provide an electronic control device that can flexibly cope with in-vehicle layout and assembly for each vehicle at low cost and can contribute to a reduction in the total cost of the vehicle, the following configuration is adopted. A method of manufacturing an electronic control device including a housing having a bracket for attaching the electronic control device to a predetermined position and a connector opening, the method including: manufacturing the housing by a die casting method using a cavity mold that presses the connector opening in a direction substantially perpendicular to the connector opening, a core mold that receives pressing of the cavity mold, and a slide mold that slides in a direction substantially perpendicular to the pressing direction; manufacturing an attachment surface of the bracket integrally with the housing so as to have a surface horizontal to a pressing surface of the slide mold; and further performing cutting work such that only one slide mold is used, the attachment surface of the bracket which is not pressed by the slide mold has a cut tapered surface of the cavity mold, and the cut tapered surface is cut and processed so as to be a surface parallel to a surface horizontal to the pressing surface of the slide mold after mold release.

### TECHNICAL FIELD

The present invention relates to an electronic control device including a circuit board on which a connector for external connection is mounted, and a housing accommodating the circuit board and the connector, and particularly relates to an electronic control device used by being attached to a vehicle, and a method of manufacturing the same.

### BACKGROUND ART

In recent years, vehicles are controlled by a large number of electronic devices such as an engine control unit (ECU) and an advanced driving assistance system (ADAS). A printed circuit board (PCB) of such an electric device is generally accommodated in a case (housing) having a waterproof property to prevent entry of moisture. Further, a heat sink (heat dissipation fin) is generally provided in a case for radiating heat emitted from an electronic device mounted on a PCB.

In addition, since the circuit board (PCB) is provided with a connector for extracting a signal to the outside, the case is provided with an opening for the connector. The housing is generally constituted by a pair of cases that can be vertically divided from the viewpoint of ease of manufacturing and the like. The heat dissipation fin described above is integrally formed with one of the pair of cases. When the case including the heat dissipation fin is a die-cast product using an aluminum material or the like having good thermal conductivity, the heat dissipation effect is enhanced. Such an electronic control device is disclosed in, for example, Patent Literature 1.

The housing of the electronic control device disclosed in Patent Literature 1 accommodates the remaining portion of the connector and the circuit board in the internal space while exposing a part of the connector to the outside through a connector opening formed in a state where the upper first case and the lower second case are assembled. The first case and the second case are die-cast products made of aluminum. A plurality of heat dissipation fins are integrally formed on an upper surface of the first case.

### CITATION LIST

### Patent Literature

PTL 1: JP 2016-143852 A

### SUMMARY OF INVENTION

### Technical Problem

An in-vehicle layout and an assembling method of such an electronic control device are different for each vehicle, and even when an electronic control device having the same housing is attached, it is necessary to individually design and manufacture the mounting bracket for each vehicle type, which leads to an increase in cost.

An object of the present invention is to provide an electronic control device that can flexibly cope with in-vehicle layout and assembly for each vehicle at low cost and can contribute to a reduction in the total cost of the vehicle.

### Solution to Problem

The configuration of the present invention for achieving the above object is as follows.

A method of manufacturing an electronic control device including a housing having a bracket for attaching the electronic control device to at least a predetermined position and a connector opening, the method including: manufacturing the housing by a die casting method using a cavity mold that presses the connector opening in a direction substantially perpendicular to the connector opening, a core mold that receives pressing of the cavity mold, and a slide mold that slides in a direction substantially perpendicular to the pressing direction; and manufacturing an attachment surface of the bracket integrally with the housing so as to have a surface horizontal to a pressing surface of the slide mold, and an electronic control device manufactured by the manufacturing method.

### Advantageous Effects of Invention

To provide an electronic control device that can flexibly cope with in-vehicle layout and assembly for each vehicle at low cost and can contribute to a reduction in the total cost of the vehicle.

### BRIEF DESCRIPTION OF DRAWINGS

FIG. 1 is a cross-sectional view of an electronic control device according to the present invention.

FIG. 2 is a perspective view of a first case illustrated in FIG. 1.

FIG. 3 is a perspective view of the electronic control device according to the present invention.

FIG. 4 is a perspective view of an upper case of the electronic control device illustrated in FIG. 3.

FIG. 5 is a schematic view of a mold when the upper case of the present invention is cast.

FIG. 6 is another example of a schematic view of a mold when the upper case of the present invention is cast.

FIG. 7 is a view illustrating a structure of a bracket of the upper case of the present invention.

FIG. 8 is a view showing a bolt fastening surface of the bracket of the upper case of the present invention.

FIG. 9 is a view illustrating an example in which the bracket of the upper case of the present invention is formed in an L shape.

FIG. 10 is a diagram showing a manufacturing flow of the upper case of the present invention.

FIG. 11 is a diagram illustrating a conventional electronic control device.

### DESCRIPTION OF EMBODIMENTS

Embodiments of the present invention will be described below with reference to the accompanying drawings. The embodiment illustrated in the accompanying drawings is an example of the present invention, and the present invention is not limited to the embodiment. In the drawing, Up indicates an upper side, and Dn indicates a lower side.

### Example 1

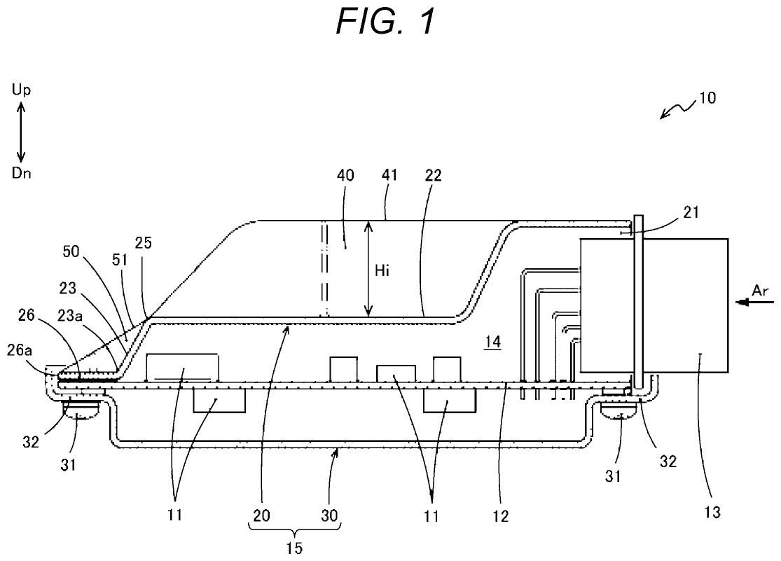

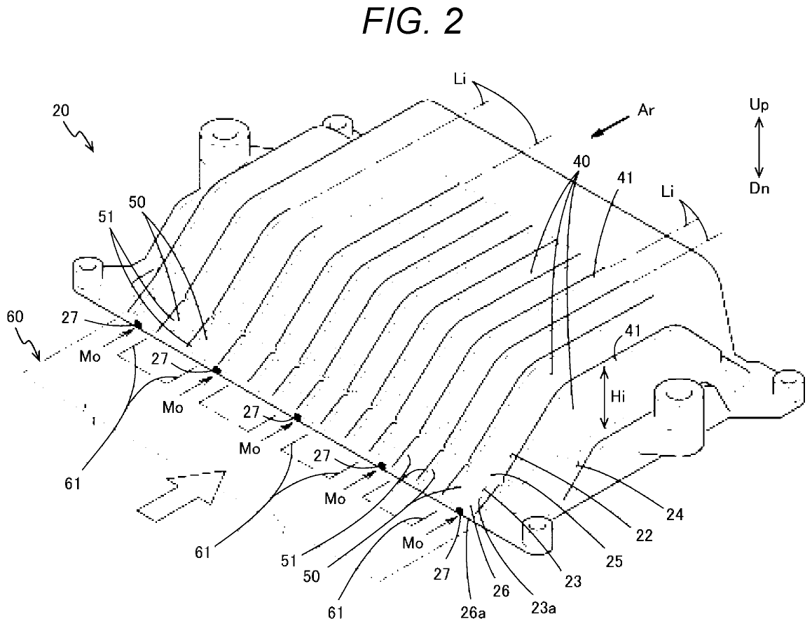

An electronic control device 10 according to Example 1 will be described with reference to FIGS. 1 and 2.

As illustrated in FIG. 1, the electronic control device 10 includes a circuit board 12 on which electronic components 11 are mounted, a connector 13 for external connection mounted on the circuit board 12, and a housing 15 having an internal space 14 that houses the circuit board 12.

The housing 15 includes a first case 20 whose lower side is opened and a second case 30 whose upper side is opened. The internal space 14 is formed in the housing 15 by overlapping the upper first case 20 and the lower second case 30 and assembling them with screws 31.

The first case 20 is a die-cast product of a light metal having excellent thermal conductivity, such as aluminum (including an aluminum alloy). The second case 30 is a press-molded product of a metal plate.

Further, the housing 15 has a connector opening 21 formed in a state where the first case 20 and the second case 30 are assembled. The connector opening 21 is formed only in the first case 20, for example. The housing 15 accommodates the remaining portion of the connector 13 and the circuit board 12 in the internal space 14 while exposing a part of the connector 13 to the outside through the connector opening 21. The housing 15 may have a configuration in which the first case 20 and the second case 30 are turned upside down.

As shown in FIGS. 1 and 2, the first case 20 has a surface 22 (upper surface 22) opposite to the second case 30, a back surface 23 opposite to the connector opening 21, and left and right side surfaces 24 (only one side is shown) as viewed from the connector opening 21 side (as viewed from the Ar arrow line-of-sight direction). The upper surface 22 is a flat plane.

FIG. 3 is a perspective view of the electronic control device 100 according to the present invention.

The electronic control device 100 is used such that a body bracket 101 to be attached to a vehicle side is screwed to a bracket 102. The body-side bracket 101 is screwed and fixed to a vehicle side to be attached. The body-side bracket 101 may have various shapes depending on a mounting structure to the vehicle side. Reference numeral 102 denotes an upper case, reference numeral 104 denotes a heat dissipation fin provided in the upper case 103, reference numeral 105 denotes a connector, and reference numeral 108 denotes a lower case for fixing a circuit board.

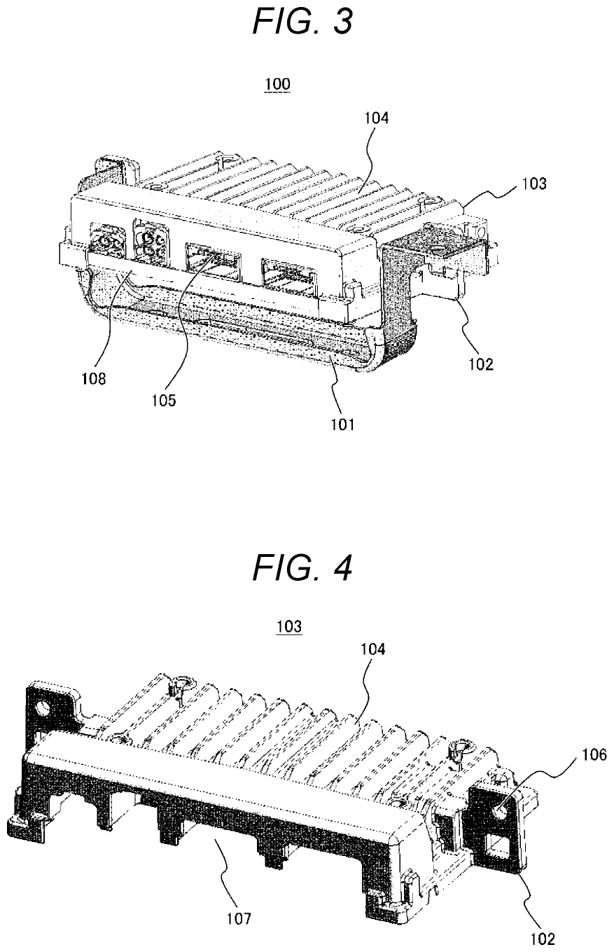

FIG. 4 is a perspective view of the upper case 103 of the electronic control device of FIG. 3.

A screw mounting hole 105 of the bracket 102 is visible. A screw is inserted into the screw mounting hole to fasten the body-side bracket 101. The connector opening 107 is an opening into which the connector enters when the upper case 103 is united with the lower case 108.

That is, the upper case 103 is a die-cast housing having the connector opening 107, and the bracket (attachment portion) 102 is integrally formed with the housing.

An attachment surface of the bracket (attachment portion) 102 is configured to be parallel to the opening direction of the connector opening 107. With this configuration, when the electronic control device is installed on the vehicle side, the attachment of the connector and the attachment direction of the screw to the bracket 102 can be made the same, so that the attachment work is facilitated. Furthermore, since the work direction can be only one surface, the work space can be reduced, and an effect of improving the degree of freedom in mounting in retrofitting or the like can also be expected.

Next, a manufacturing process of the upper case 103 will be described.

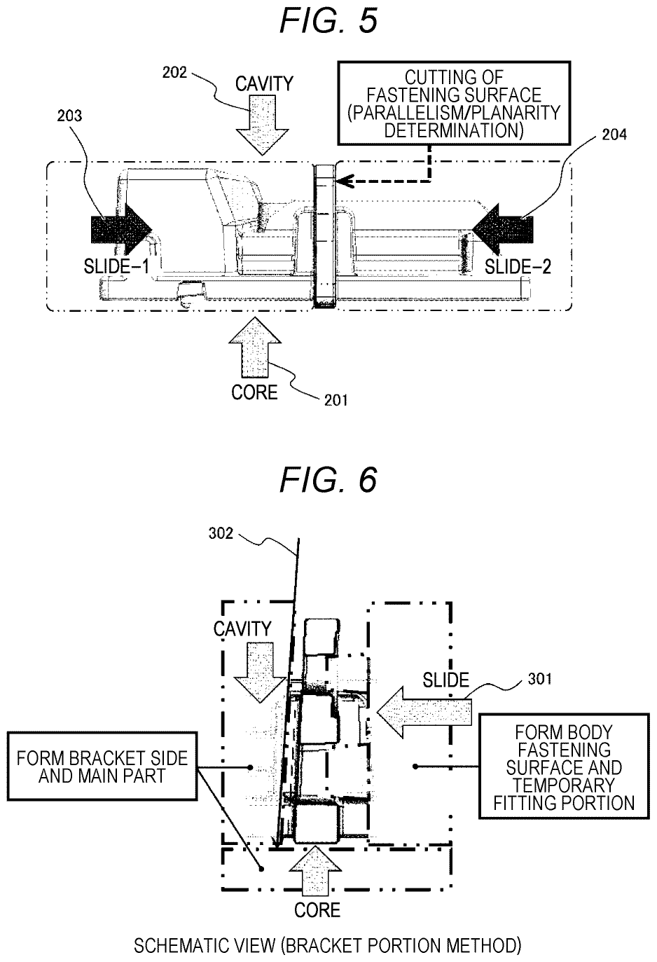

The upper case 103 is manufactured by a die casting method. A manufacturing method will be described with reference to FIG. 5. The upper case 103 is casted such that the upper case 103 is pressed by being sandwiched with a fixed mold (core) 201 and a movable mold (cavity) 202 from the vertical direction of the upper case, and at the same time, he upper case 103 is mold-divided by the pair of slide molds (core molds) 203 and 204 so as to be pressed in a direction perpendicular to the connector opening.

At this time, the attachment surface of the bracket 102 can be changed in a direction of 360 degrees with respect to the connector opening surface by changing the pressing surface angle of the slide mold.

In addition, parallelism and planarity determination of the screw fastening surfaces of the bracket 102 can be determined by forming a pair of slide molds, but die casting using a total of four molds may cause problems of an increase in manufacturing cost and complication of mold maintenance.

As a method for solving such a problem, as illustrated in FIG. 6, the mold can be configured such that accuracy is achieved using the slide mold 301 only on the side on which the body-side bracket 101 is fastened, and the side on which the body-side bracket 101 is not fastened has a taper (extraction taper) 302 through which the cavity mold is removed. In this case, it is effective to perform leveling such that a tapered surface for removing the influence of the extraction taper of the attachment portion is parallel to the opposing surface.

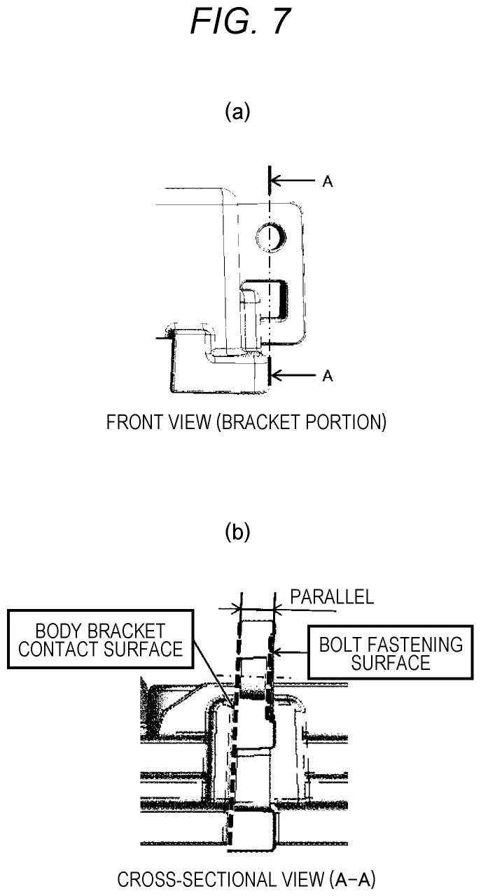

This will be described with reference to FIG. 7. FIG. 7(a) is a front view of the bracket 102, and FIG. 7(b) illustrates an A-A cross section of FIG. 7(a). As illustrated in FIG. 7(b), it is effective to perform cutting so that the surface (contact surface) with which the body bracket 101 is in contact becomes parallel to the opposing bolt (screw) fastening surface.

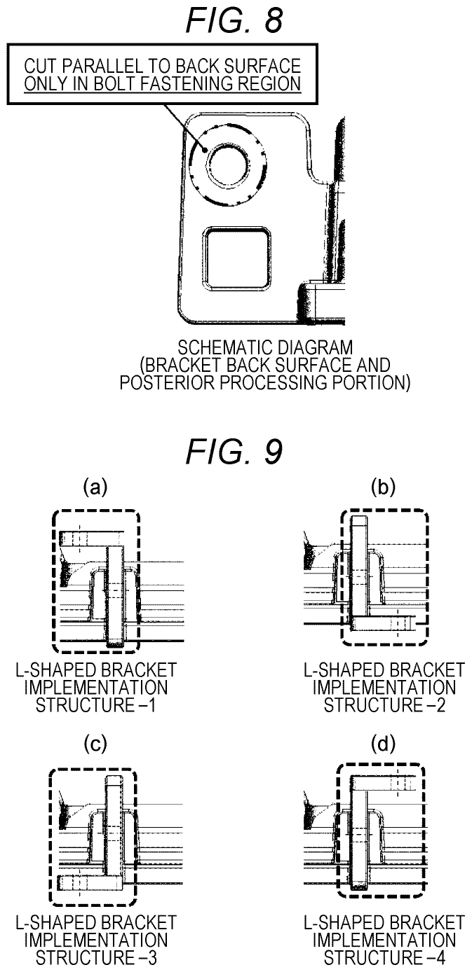

In this case, as illustrated in FIG. 8, in order to shorten the cutting processing time, it is effective to form the fastening surface parallel to the back surface only in the bolt fastening region by post-processing. Accordingly, the proper axial force of the screw can be ensured.

The bracket may have an L shape as illustrated in FIG. 9(a) to 9(d). This structure may improve the mutual assembling property with the vehicle-side bracket.

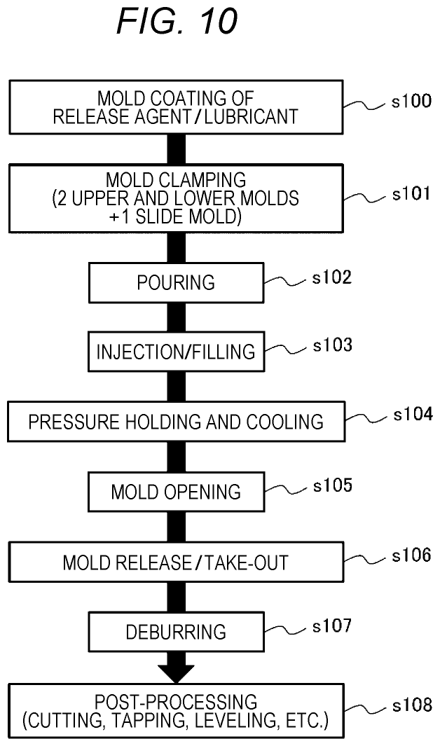

FIG. 10 shows a manufacturing flow of the upper case 103 of the present invention.

First, apply a mold release agent and a lubricant to a die casting mold (step s100). Next, align a core mold which is a fixed mold, a cavity mold which is a movable mold, and a slide mold (in this drawing, one slide mold) for producing a bracket with a pouring position (mold clamping: step s101). Pour melted aluminum into the aligned molds (pouring: step s102). Move the cavity mold which is a movable mold and the slide mold to perform injection and filling of a molten metal (step s103). Cool melted metal until the melted metal is solidified while maintaining the pressure applied to the mold (step s105). Open the mold after the cooling is finished (step s105). Release the die-cast casting from the mold (mold release/take-out step s106). Remove burr of the taken-out casting using a grinder or the like (deburring step s107).

Post-process step (s108), such as cutting, tapping, leveling, etc.

In such a process, the upper case of the present invention is manufactured.

### Comparative Example

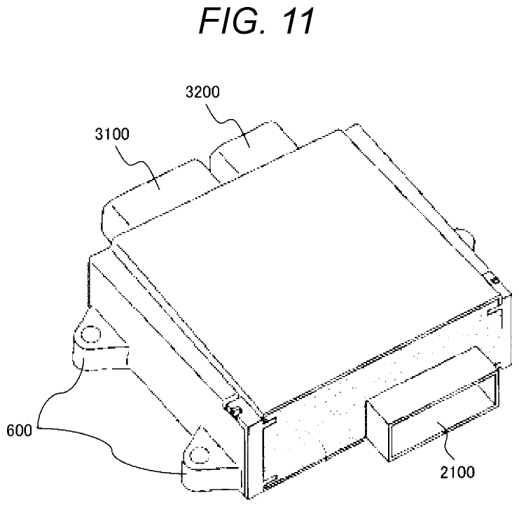

FIG. 11 is a diagram illustrating a conventional electronic control device. The connector openings are 2100, 3100, and 3200. The bracket is 600. The upper case of the conventional electronic control device was generally manufactured with only two molds, i.e., a cavity mold and a core mold, with emphasis on ease of manufacturing. Therefore, the bracket 600 had a fastening surface parallel to the circuit board (that is, perpendicular to the connector opening surface).

In a case where the bolt (screw) fastening surface of the bracket 600 is perpendicular to the connector opening surface, it was necessary to use a large number of screws when the body bracket was attached to the upper case.

In addition, since it is necessary to apply a screwdriver in a direction perpendicular to the longitudinal direction of the screw when fastening the screw, it was necessary to fasten the screw with the screwdriver directed in a different direction. If the insertion direction of the connector and the fastening direction of the screw are different, the work of assembling the electronic control device to the vehicle became complicated, and a corresponding work space was required.

### REFERENCE SIGNS LIST

10, 100 electronic control device
12 circuit board
13 connector
14 internal space
15 housing
20, 120 first case
21 connector opening
22 surface (upper surface) opposite to second case
23 back surface opposite to connector opening
25 boundary between upper surface and back surface
27 trace
30 second case
40 heat dissipation fin

1. A method of manufacturing an electronic control device including a housing having a bracket for attaching the electronic control device to at least a predetermined position and a connector opening, the method comprising:
manufacturing the housing by a die casting method using a cavity mold that presses the connector opening in a direction substantially perpendicular to the connector opening, a core mold that receives pressing of the cavity mold, and a slide mold that slides in a direction substantially perpendicular to the pressing direction;
manufacturing an attachment surface of the bracket integrally with the housing as to have a surface horizontal to a pressing surface of the slide mold; and
further performing cutting work such that only one slide mold is used, the attachment surface of the bracket which is not pressed by the slide mold has a cut tapered surface of the cavity mold, and the cut tapered surface is cut and processed so as to be a surface parallel to a surface horizontal to the pressing surface of the slide mold after mold release.

2. The method of manufacturing an electronic control device according to claim 1, wherein
the cutting work cuts only the vicinity of a fastening surface of a screw for fixing the bracket.

3. The method of manufacturing an electronic control device according to claim 1, wherein
the bracket has a second attachment surface substantially perpendicular to the attachment surface having a surface horizontal to the pressing surface of the slide mold.

4. An electronic control device, comprising a housing including a bracket for attaching the electronic control device to at least a predetermined position and a connector opening, wherein
the housing has attachment surfaces of the bracket on a surface substantially parallel to the connector opening, and the attachment surfaces are integrated with the housing,
further, one of the attachment surfaces of the bracket has a cut tapered surface of a die casting mold, and
at least a part of the cut tapered surface of the die casting mold is processed to be a surface parallel to the other attachment surface of the bracket.

5. The electronic control device according to claim 4, wherein
the surface processed to be a surface parallel to the other attachment surface of the bracket is only in the vicinity of a fastening surface of a screw for fixing the bracket.
